(19) United States
(12) Patent Application Publication
(10) Pub. No.: US 2011/0263098 A1
(43) Pub. Date: Oct. 27, 2011

(54) HYBRID DEPOSITION CHAMBER FOR IN-SITU FORMATION OF GROUP IV SEMICONDUCTORS & COMPOUNDS WITH GROUP III-NITRIDES

(75) Inventor: Jie SU, Santa Clara, CA (US)

(73) Assignee: Applied Materials, Inc., Santa Clara, CA (US)

(21) Appl. No.: 13/045,369

(22) Filed: Mar. 10, 2011

Related U.S. Application Data
(60) Provisional application No. 61/327,469, filed on Apr. 23, 2010.

(51) Int. Cl. H01L 21/20; C23C 16/00

(52) U.S. Cl. 438/478; 118/715; 118/719; 257/E21.119

(57) ABSTRACT

Hybrid MOCVD or HVPE epitaxial system for in-situ epitaxially growth of group III-nitride layers and group IV semiconductor layers and/or group IV compounds. A hybrid deposition chamber is coupled to each of a first and second precursor delivery system to grow both a transition film comprising either group IV semiconductor or group IV compound and a film comprising a group III-nitride on the transition film. In one embodiment, the first precursor delivery system is coupled to both a silicon precursor and a second group IV precursor while the second precursor delivery system is coupled to a metalorganic precursor. In embodiments, a layer comprising a silicon semiconductor is deposited over a substrate and a group III-nitride epitaxial film is then deposited in-situ over the substrate.

### CROSS-REFERENCE TO RELATED APPLICATIONS

This application claims the benefit of U.S. Provisional Application No. 61/327,469 filed on Apr. 23, 2010, entitled “HYBRID DEPOSITION APPARATUS FOR EPITAXY OF GALLIUM NITRIDE ON SILICON,” the entire contents of which are hereby incorporated by reference herein.

### BACKGROUND

1. Field

Embodiments of the present invention pertain to the field of group III-nitride thin film epitaxy and, in particular, to growth of group III-nitride thin film structures with Group IV semiconductors and compounds.

2. Description of Related Art

Group III-nitride materials are playing an ever increasing role in semiconductor devices (e.g., power electronics and light-emitting diodes (LEDs). Many such devices rely on an epitaxial growth of group III-nitride films, such as gallium nitride (GaN). The growth of such nitride films is typically via heteroepitaxy on a substrate such as, for example single crystalline sapphire, silicon carbide (SiC), gallium arsenide (GaAs), zinc oxide (ZnO). Recently, extensive work has been directed toward heteroepitaxy of GaN on silicon (Si) substrates. However, the significant difference between the GaN lattice structure (hexagonal wurtzite) and lattice parameter (a=3.189 Å) and the Si latter structure (face-centered cubic) and lattice parameter (a=5.431 Å), the significant difference in thermal expansion coefficients, and different in interfacial surface energy all present challenges to the formation of GaN on Si.

In an effort to overcome these challenges, various buffer or transition layers have been studied, such as an aluminum nitride (AlN), graded aluminum-gallium-nitride (AlGaN), AlGaN/GaN superlattice structures, and GaAs layers. While such buffer layers can modify the surface energy of the underlying Si substrate and alleviate the intrinsic stress within the lattice-matched nitride layers, the large difference in the thermal expansion coefficients can lead to cracking during thermal cycling. Recently, silicon germanium transition layers have met with some success in forming a matching thermal expansion interface between silicon and GaN.

### BRIEF DESCRIPTION OF THE DRAWINGS

Embodiments of the present invention are illustrated by way of example, and not by way of limitation, in the figures of the accompanying drawings, in which:

FIG. 1A is a flow diagram illustrating a method for epitaxial growth of a GaN thin film layer following in-situ growth of a silicon alloy transition layer, in accordance with an embodiment of the present invention;

FIG. 1B illustrates a schematic of a GaN stack including a silicon alloy transition layer, in accordance with an embodiment of the present invention;

FIG. 2 is a schematic cross-sectional view of a hybrid MOCVD chamber configured to grow both a silicon alloy transition layer and a GaN device layer, in accordance with an embodiment of the present invention;

FIG. 3 is a schematic view of an HVPE apparatus configured to grow both a silicon alloy transition layer and a GaN device layer, in accordance with an embodiment of the present invention;

FIG. 4 is a schematic plan view of a multi-chambered epitaxy system including a plurality of chambers, each chamber configured to grow both a silicon alloy transition layer and a GaN device layer, in accordance with an embodiment of the present invention; and

FIG. 5 is a schematic of a computer system, in accordance with an embodiment of the present invention.

### DETAILED DESCRIPTION

In the following description, numerous details are set forth. It will be apparent, however, to one skilled in the art, that the present invention may be practiced without these specific details. In some instances, well-known methods and devices are shown in block diagram form, rather than in detail, to avoid obscuring the present invention. Reference throughout this specification to “an embodiment” means that a particular feature, structure, function, or characteristic described in connection with the embodiment is included in at least one embodiment of the invention. Thus, the phrase “in an embodiment” in various places throughout this specification is not necessarily referring to the same embodiment of the invention. Furthermore, the particular features, structures, functions, or characteristics may be combined in any suitable manner in one or more embodiments. For example, a first embodiment may be combined with a second embodiment anywhere the two embodiments are not mutually exclusive.

Many electronic devices, such as power transistors, as well as optical and optoelectronic devices, such as Light-emitting diodes (LEDs), may be fabricated from layers of group III-nitride films. Described herein are embodiments of hybrid deposition chambers to form both group III-nitride layers and group IV semiconductor layers and/or group IV compound layers with without interruption. Exemplary embodiments of the present invention relate to the heteroepitaxial growth of germanium-containing and or/silicon-containing layers in-situ with group III-nitride films, such as GaN. While the in-situ heteroepitaxial growth may be performed such that the group IV semiconductor layers and/or group IV compound layers are formed after growth of the group III-nitride film (e.g., silicon alloy film formed on a GaN film), in the exemplary embodiment the group III-nitride film is grown after growth of the group IV semiconductor layers and/or group IV compound layers (e.g., GaN film form on a silicon-containing film). In one such embodiment, a group IV transition layer between a silicon substrate and a crystalline nitride film is grown in-situ with growth of the nitride film. As used herein, “in-situ” entails growing of both the group IV layer(s) and group-III nitride layers without interruption and without cycling the substrate temperature below that of the lowest deposition temperature between growths of the separate film layers. For example, in an in-situ growth of a SiGe—GaN interface, after growth of a SiGe transition layer, vacuum is not broken and the substrate is not cooled to a temperature below the silicon alloy deposition temperature prior to deposition of the group III-nitride film deposition. This in-situ growth of group IV semiconductor films and/or group IV compound films with group III-nitride films described herein is well-suited for forming transition layers matching thermal expansion between that of a silicon substrate and an overlying nitride crystalline film (e.g., group III-nitrides, such as GaN).

In alternative embodiments where the group IV layer formed by the hybrid deposition chamber is an amorphous silicon based compound, such as silica (SiO₂) or silicon nitride (Si₃N₄), structures like ¼ wavelength multi-layered SiO₂/Si distributed bragg reflector (DBR) mirrors, for example, may be formed in-situ with group III-nitride layers.

Further embodiments include a hybrid deposition system providing for metalorganic chemical vapor deposition (MOCVD) or a hydride/halide vapor phase epitaxy (HVPE) of the nitride epitaxial film and further providing for CVD of the silicon alloy or silicon compound film. In a preferred embodiment, a group IV semiconductor epitaxy capability is provided in the hybrid MOCVD and HVPE system as a single chamber solution to the in-situ growth of a silicon alloy-group III-nitride epitaxial stack, which may further include a nucleation layer between the group IV semiconductor layer and group III-nitride layer. While numerous examples are provided herein of a modular chamber approach in which a transfer chamber module couples a plurality of chamber modules to form a cluster tool, it is to be appreciated that an in-line epitaxial system in which a substrate is conveyed from a first chamber portion to a second chamber portion between epitaxial depositions may also be utilized to practice embodiments of invention described herein.

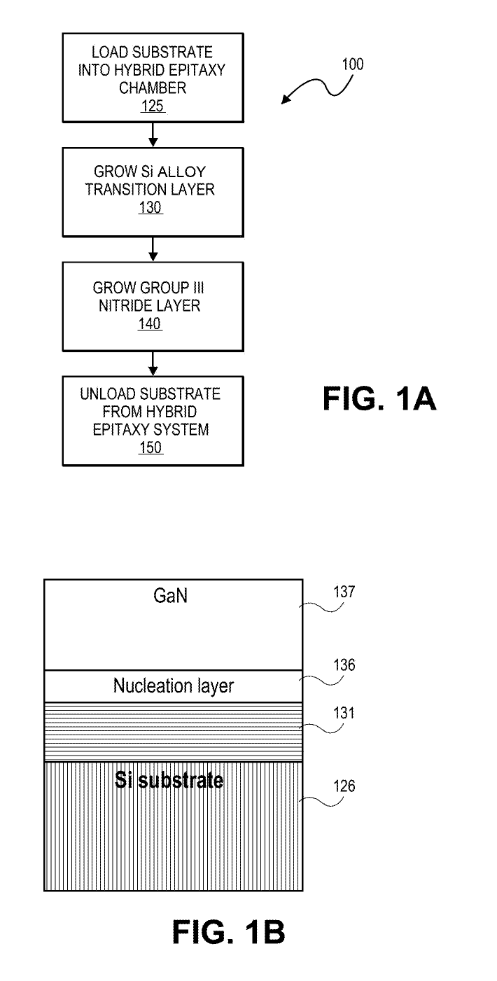

In an embodiment, in-situ growth of a group IV semiconductor layer and/or group IV compound layer (e.g., crystalline silicon alloy or non-crystalline silicon compound) with group III-nitride includes loading a substrate into a hybrid deposition chamber, depositing a group IV semiconductor epitaxial layer and/or group IV compound amorphous layer over the substrate, depositing a group III-nitride epitaxial film over the substrate, and unloading the substrate from the epitaxy chamber. As an exemplary embodiment, FIG. 1A illustrates an in-situ epitaxial growth method 100 forming a silicon alloy-GaN epitaxial film stack. FIG. 1B illustrates a schematic of a GaN stack including a silicon alloy transition layer which may be formed by the in-situ epitaxial growth method 100 in accordance with embodiments of the present invention.

In FIG. 1A, the method 100 begins with loading a substrate in a hybrid epitaxy chamber at operation 125. Generally, the substrate may be any commonly used in the art, such as, but not limited to, single crystalline sapphire, germanium (Ge), silicon carbide (SiC), gallium arsenide (GaAs), zinc oxide (ZnO), lithium aluminum oxide (γ-LiAlO₂). However, in the exemplary embodiment illustrated in FIG. 1B, the substrate is a silicon substrate 126. The silicon substrate 126 may be any bulk or epitaxial single crystalline silicon having a crystallographic orientation of (111), (100) and (110). In a further embodiment, the silicon substrate 126 has an “off-cut” crystallographic orientation whereby the growth surface is 2-3° off of the major crystal axis to present a higher order plane as the growth surface.

Returning to FIG. 1A, at operation 130 a silicon alloy is epitaxially grown on the substrate. In the exemplary embodiment depicted in FIG. 1B, the silicon alloy epitaxial layer grown is a transition layer 131 grown directly on the silicon substrate 126. The silicon alloy may be grown as a compositionally graded alloy or to have a superlattice structure. The constituents of the silicon alloy include silicon and any of germanium (Ge), carbon (C), and tin (Sn). In particular embodiments the silicon alloy is a binary alloy such as SiGe or SiC, but in alternative embodiments, ternary alloys, etc. may also be formed (SiC:Ge). Additionally, impurity dopants may (e.g., carbon, boron, nitrogen etc.) further be provided at low to moderate concentrations in the alloy matrix. In the exemplary embodiment depicted in FIG. 1B, the transition layer 131 is silicon germanium (SiGe) which may be compositionally graded or form a superlattice to satisfy thermal expansion and lattice matching functions, as known in the art.

In one embodiment, the silicon substrate 126 is heated to a temperature between 600° C. and 900° C. during formation of the SiGe transition layer 131 at operation 130. Growth of the SiGe transition layer 131 is to be distinguished from merely doping an epitaxial film with silicon and/or germanium. In particular, to form the SiGe transition layer 131, each of a silicon precursor and a germanium precursor is introduced at a rate of at least 10 liters/min. Depending on the embodiment, the flow rate of the germanium precursor may be 20 liters/min or more, as may be the flow rate of the silicon precursor. Although any precursors known in the art may be used to form the SiGe transition layer 131, exemplary embodiments include a silicon precursor of silicon tetrachloride, silane, dichlorosilane, or trichlorosilane and a germanium precursor of germane, di-germane, and germanium tetrachloride.

Returning to FIG. 1A, at operation 140 a group III-nitride epitaxial film is grown directly on the silicon alloy epitaxial layer. The group III-nitride epitaxial film may include any group III element alloyed with nitrogen, such as aluminum (Al), gallium (Ga), and indium (In). In a particular embodiment, the group III-nitride is a binary alloy, but in alternative embodiments, ternary alloys (e.g., AlGaN) and higher may also be formed. Additionally, impurity dopants may (e.g., silicon, magnesium, etc.) further be provided at low to moderate concentrations in the alloy matrix. In the exemplary embodiment depicted in FIG. 1B, the group III-nitride epitaxial film is a gallium nitride (GaN) film 137. As illustrated, the GaN film 137 is formed over the SiGe transition layer 131.

In particular embodiments, growth of the GaN film 137 (e.g., at operation 140) is preceded by deposition of a nucleation layer 136. The nucleation layer 136 may be any known in the art for growth of GaN films, such as but not limited to aluminum nitride (AlN), graded AlₓGa₁₋ₓN, or AlₓGa₁₋ₓN/GaN superlattice. In embodiments, the group III-nitride epitaxial film is grown at operation 140 without cycling the temperature of the substrate down below the silicon alloy growth temperature employed at operation 130.

In embodiments, the silicon alloy growth operation 130 may complicate group III-nitride film growth operation 140, for example where a silicon alloy constituent tends to form deposits on a deposition chamber interior. In one such embodiment where the silicon alloy layer 137 is SiC grown at operation 130, and during operation 140 the nucleation layer 136 is formed in-situ with a remainder of the GaN layer 137 is then formed in a separate deposition chamber which is to remain carbon-free.

Generally, the group III-nitride growth temperature will be higher than that of the silicon alloy epitaxial layer and therefore where growth operation 140 is performed in the same epitaxial chamber as nucleation layer 136, the in-situ growth process may proceed with a ramp in temperature after termination of the silicon alloy growth (or during a last portion of that growth) and either prior to growth of the group III-nitride or during an initial portion of that growth (or nucleation layer growth). For such an in-situ growth of both the silicon alloy and group III-nitride, the silicon alloy and group III-nitride films may be grown without interruption. The ability to grow Si alloys and III-nitride in the same chamber can have some advantages, for example, there is no need for extra surface passivation or cleaning steps in between the two layers to avoid any native oxide layer or foreign impurities which could occur during the growth interruption if they are done in different chambers. Furthermore, thermal cycling of the substrate during transfers between chambers may be avoided, improving thermal budget for a device film stack.

In a particular embodiment employed to form the stack depicted in FIG. 1B, the silicon substrate 126 is heated to a temperature of at least 900° C., and preferably at least 1000° C., during formation of the GaN film 137 at operation 130. In one such embodiment, subsequent to epitaxial growth of the SiGe transition layer 131, the silicon substrate 126 is heated from the 600-900° C. temperature employed for the growth of the SiGe to the GaN film growth temperature without cycling the temperature of the silicon substrate 126 down below the SiGe growth temperature. Any metalorganic precursors known in the art may be used to form the group III-nitride film, exemplary precursors for the GaN film 137 include trimethylgallium (TMG), and triethylgallium (TEG).

In reference to FIG. 1, following deposition of the group III-nitride film at operation 140, one or more active device layers (e.g., n-type power FET channel layers, P-i-N/MQW LED layers, etc.) may be formed over the group III-nitride film. It should also be appreciated that additional silicon alloy layers may similarly be deposited over the group III-nitride film and even a pure silicon layer then formed over the silicon alloy layer if desired. Such device layer depositions may be performed in the hybrid epitaxy system prior to unloading the substrate at operation 150 or subsequent to unloading the substrate from hybrid epitaxy system at operation 150.

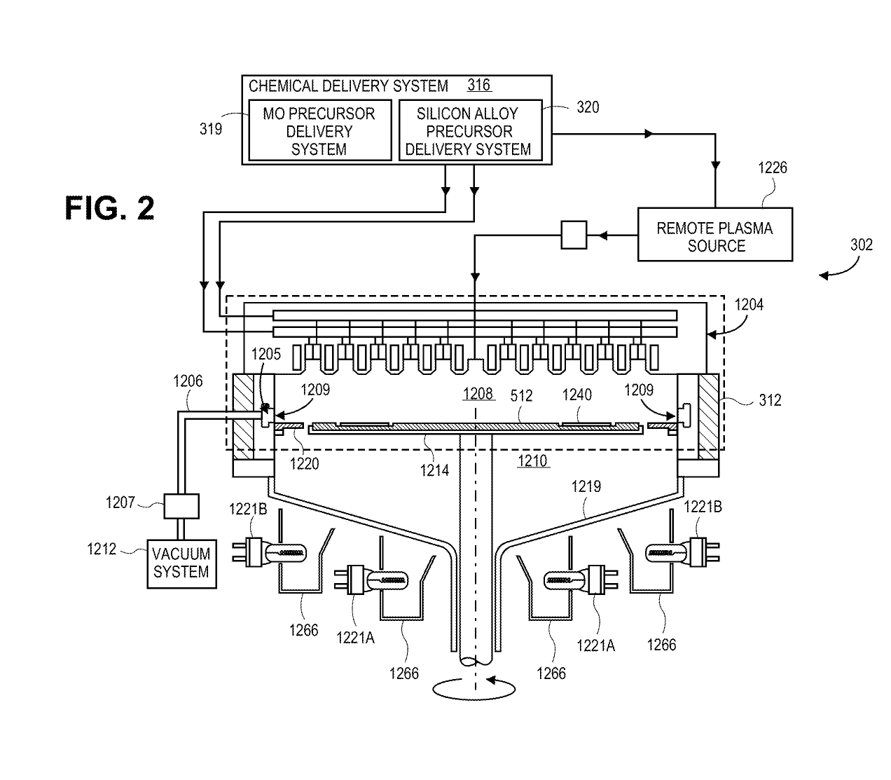

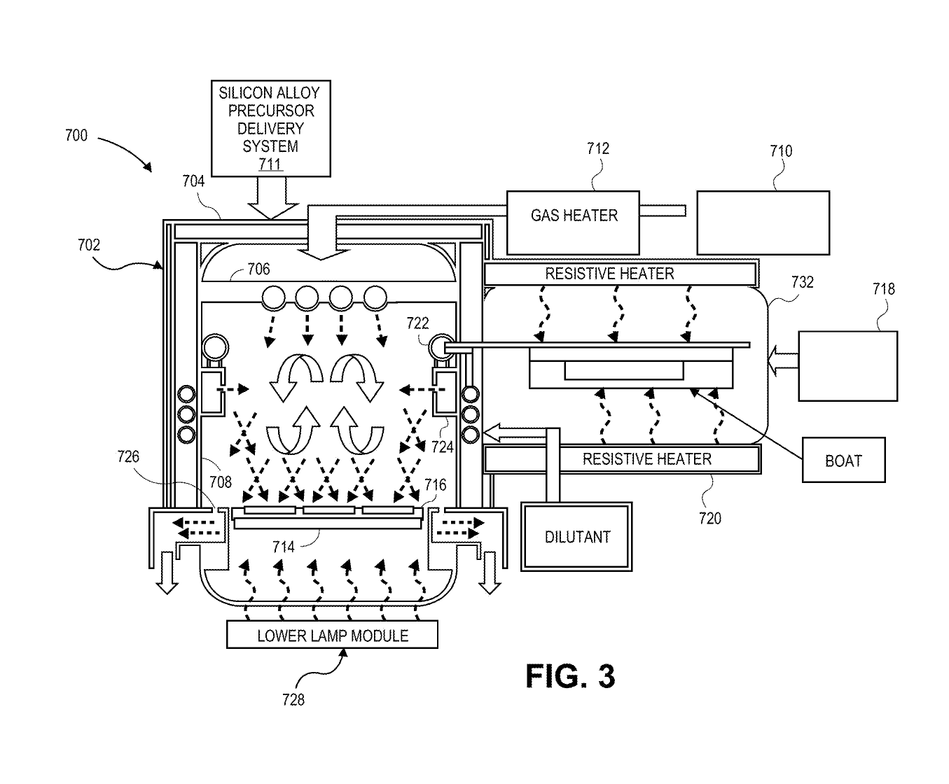

In embodiments, the silicon alloy-group III nitride layers described in reference to FIGS. 1A and 1B may be grown by either of the hybrid epitaxy chambers depicted in FIGS. 2 and 3. FIG. 2 is a schematic cross-sectional view of a hybrid MOCVD chamber which can be utilized in embodiments of the invention. The hybrid MOCVD chamber 302 comprises a chamber body 312, a chemical delivery module 316, a remote plasma source 1226, a substrate support 1214, and a vacuum system 1212. For the hybrid MOCVD chamber 302, the chemical delivery module 316 supplies chemicals to the hybrid MOCVD chamber 302 to perform both MOCVD with metalorganic precursor for group III-nitride film growth and CVD with non-metalorganic precursors for group IV semiconductor and/or group IV compound layer growth. Thus, the chemical delivery module 316 includes both a precursor delivery system 320 configured to be coupled to each of a silicon precursor source and an alloy precursor source and a second precursor delivery system 319 configured to be coupled to a metalorganic precursor source. In particular embodiments, the precursor delivery system 320 is configured to provide a silicon precursor to the hybrid MOCVD chamber 302 at a flow rate of least 10 liters/min and preferably at least 20 liters/min. In further embodiments, the precursor delivery system 320 is configured to provide a germanium precursor to the hybrid deposition chamber at a flow rate of least 10 liters/min, and preferably at least 20 liters/min. The precursor delivery system 320 may alternatively be configured to provide similar flows of other reactive gases to form alternate alloys of silicon, such as carbon (C) or tin (Sn). In further embodiments, the precursor delivery system 320 is configured to provide oxidizers, such as O₂, ozone, etc., to facilitate deposition of silicon-containing non-crystalline compounds (e.g., SiO₂, Si3N₄). In certain such embodiments, the precursor delivery system 320 provides silica precursors (e.g., TEOS or others known in the art) to the hybrid MOCVD chamber 302.

Reactive and carrier gases are supplied from the chemical delivery system through supply lines into a gas mixing box where they are mixed together and delivered to respective showerheads 1204 and 1104. Generally supply lines for each of the gases include shut-off valves that can be used to automatically or manually shut-off the flow of the gas into its associated line, and mass flow controllers or other types of controllers that measure the flow of gas or liquid through the supply lines. Supply lines for each of the gases may also include concentration monitors for monitoring precursor concentrations and providing real time feedback, backpressure regulators may be included to control precursor gas concentrations, valve switching control may be used for quick and accurate valve switching capability, moisture sensors in the gas lines measure water levels and can provide feedback to the system software which in turn can provide warnings/alerts to operators. The gas lines may also be heated to prevent precursors and etchant gases from condensing in the supply lines. Depending upon the process used some of the sources may be liquid rather than gas. When liquid sources are used, the chemical delivery module includes a liquid injection system or other appropriate mechanism (e.g. a bubbler) to vaporize the liquid. Vapor from the liquids is then usually mixed with a carrier gas as would be understood by a person of skill in the art.

The hybrid MOCVD chamber 302 includes a chamber body 312 that encloses a processing volume 1208. A showerhead assembly 1204 is disposed at one end of the processing volume 1208, and a carrier 512 is disposed at the other end of the processing volume 1208. The carrier 512 may be disposed on the substrate support 1214. Exemplary showerheads that may be adapted to practice the present invention are described in U.S. patent application Ser. No. 11/873,132, filed Oct. 16, 2007, entitled MULTI-GAS STRAIGHT CHANNEL SHOWERHEAD, U.S. patent application Ser. No. 11/873,141, filed Oct. 16, 2007, entitled MULTI-GAS SPIRAL CHANNEL SHOWERHEAD, and U.S. patent application Ser. No. 11/873,170, filed Oct. 16, 2007, entitled MULTI-GAS CONCENTRIC INJECTION SHOWERHEAD.

A lower dome 1219 is disposed at one end of a lower volume 1210, and the carrier 512 is disposed at the other end of the lower volume 1210. The carrier 512 is shown in process position, but may be moved to a lower position where, for example, the substrates 1240 may be loaded or unloaded. An exhaust ring 1220 may be disposed around the periphery of the carrier 512 to help prevent deposition from occurring in the lower volume 1210 and also help direct exhaust gases from the hybrid MOCVD chamber 302 to exhaust ports 1209. The lower dome 1219 may be made of transparent material, such as high-purity quartz, to allow light to pass through for radiant heating of the substrates 1240. The radiant heating may be provided by a plurality of inner lamps 1221A and outer lamps 1221B disposed below the lower dome 1219 and reflectors 1266 may be used to help control the hybrid MOCVD chamber 302 exposure to the radiant energy provided by inner and outer lamps 1221A, 1221B. Additional rings of lamps may also be used for finer temperature control of the substrates 1240.

A purge gas (e.g., nitrogen) may be delivered into the hybrid MOCVD chamber 302 from the showerhead assembly 1204 and/or from inlet ports or tubes (not shown) disposed below the carrier 512 and near the bottom of the chamber body 312. The purge gas enters the lower volume 1210 of the hybrid MOCVD chamber 302 and flows upwards past the carrier 512 and exhaust ring 1220 and into multiple exhaust ports 1209 which are disposed around an annular exhaust channel 1205. An exhaust conduit 1206 connects the annular exhaust channel 1205 to a vacuum system 512 which includes a vacuum pump (not shown). The hybrid MOCVD chamber 302 pressure may be controlled using a valve system 1207 which controls the rate at which the exhaust gases are drawn from the annular exhaust channel 1205. Other aspects of the MOCVD chamber are described in U.S. patent application Ser. No. 12/023,520, filed Jan. 31, 2008, (attorney docket no. 011977) entitled CVD APPARATUS.

Various metrology devices, such as, for example, reflectance monitors, thermocouples, or other temperature devices may also be coupled with the hybrid MOCVD chamber 302. The metrology devices may be used to measure various film properties, such as thickness, roughness, composition, temperature or other properties. These measurements may be used in an automated real-time feedback control loop to control process conditions such as deposition rate and the corresponding thickness. Other aspects of chamber metrology are described in U.S. patent application Ser. No. 61/025,252, filed Jan. 31, 2008, (attorney docket no. 011007) entitled CLOSED LOOP MOCVD DEPOSITION CONTROL.

FIG. 3 is a schematic view of a hybrid HVPE apparatus 700 which may be utilized, in accordance with embodiments of the present invention. The hybrid HVPE apparatus 700 includes a hybrid HVPE chamber 702 enclosed by a lid 704. To perform CVD with non-metalorganic precursors for silicon alloy film growth, the hybrid HVPE apparatus 700 includes a silicon alloy precursor delivery system 711 coupled to a silicon source and an alloy source (e.g., germanium source) and deliverable through a gas distribution showerhead 706. In particular embodiments, the precursor delivery system 711 is configured to provide a silicon precursor to the hybrid HVPE chamber 702 at a flow rate of least 10 liters/min and preferably at least 20 liters/min. In further embodiments, the precursor delivery system 711 is configured to provide a germanium precursor to the hybrid HVPE chamber 702 at a flow rate of least 10 liters/min, and preferably at least 20 liters/min. The precursor delivery system 711 may alternatively be configured to provide similar flows of other reactive gases to form alternate alloys of silicon, such as carbon (C) or tin (Sn).

As depicted the hybrid HVPE chamber 702 may further receive a processing gas from a first gas source 710 via the gas distribution showerhead 706. In one embodiment, the gas source 710 may comprise a nitrogen containing compound and/or silicon containing compound. In another embodiment, the gas source 710 may comprise ammonia. In one embodiment, an inert gas such as helium or diatomic nitrogen may be introduced as well either through the gas distribution showerhead 706 or through the walls 708 of the hybrid HVPE chamber 702. In further embodiments, the gas source 710 is configured to provide oxidizers, such as O₂, ozone, etc., to facilitate deposition of silicon-containing non-crystalline compounds (e.g., SiO₂, Si3N₄). In certain such embodiments, the precursor delivery system 711 provides silica precursors (e.g., TEOS or others known in the art) to the hybrid HVPE chamber 702. An energy source 712 may be disposed between the gas source 710 and the gas distribution showerhead 706. In one embodiment, the energy source 712 may comprise a heater. The energy source 712 may break up the gas from the gas source 710, such as ammonia, so that the nitrogen from the nitrogen containing gas is more reactive.

To react with the gas from the first gas source 710, precursor material may be delivered from one or more second sources 718. The precursor may be delivered to the hybrid HVPE chamber 702 by flowing a reactive gas over and/or through the precursor in the precursor source 718. In one embodiment, the reactive gas may comprise a chlorine containing gas such as diatomic chlorine. The chlorine containing gas may react with the precursor source to form a chloride. In order to increase the effectiveness of the chlorine containing gas to react with the precursor, the chlorine containing gas may snake through the boat area in the chamber 732 and be heated with the resistive heater 720. By increasing the residence time of the chlorine containing gas, the temperature of the chlorine containing gas may be controlled. By increasing the temperature of the chlorine containing gas, the chlorine may react with the precursor faster. In other words, the temperature is a catalyst to the reaction between the chlorine and the precursor.

In order to increase the reactiveness of the precursor, the precursor may be heated by a resistive heater 720 within the second chamber 732 in a boat. The chloride reaction product may then be delivered to the hybrid HVPE chamber 702. The reactive chloride product first enters a tube 722 where it evenly distributes within the tube 722. The tube 722 is connected to another tube 724. The chloride reaction product enters the second tube 724 after it has been evenly distributed within the first tube 722. The chloride reaction product then enters into the chamber 702 where it mixes with the nitrogen containing gas to form a nitride layer on the substrate 716 that is disposed on a susceptor 714 above a lower lamp heating module 728. In one embodiment, the susceptor 714 may comprise silicon carbide. The nitride layer may comprise gallium nitride for example. The other reaction products, such as nitrogen and chlorine, are exhausted through an exhaust 726.

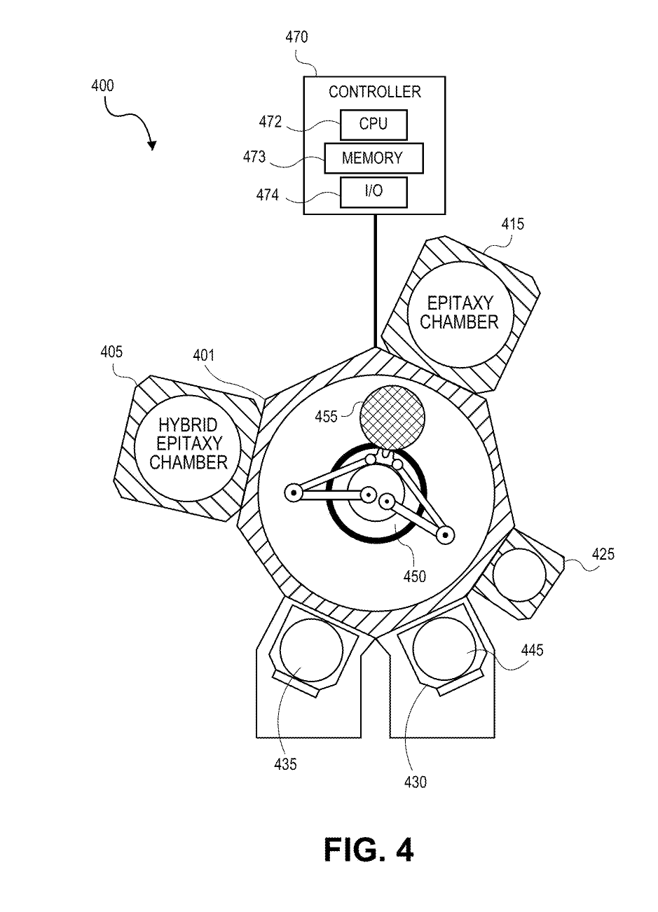

In a further embodiment, at least one hybrid epitaxy chamber, such as the hybrid MOCVD and HVPE chamber depicted in FIGS. 2 and 3, respectively, is coupled to a platform to form a multi-chambered epitaxy system. As shown in FIG. 4, the multi-chambered processing platform 400, may be any platform known in the art that is capable of adaptively controlling a plurality of process modules simultaneously. Exemplary embodiments include an Opus™ AdvantEdge™ system or a Centura™ system, both commercially available from Applied Materials, Inc. of Santa Clara, Calif.

Embodiments of the present invention further include an integrated metrology (IM) chamber 425 as a component of the multi-chambered processing platform 400. The IM chamber 425 may provide control signals to allow adaptive control of integrated deposition process, such as the multiple segmented epitaxial growth method 100. Integrated metrology may be utilized as the substrate is transferred between epitaxy chambers. The IM chamber 425 may include any metrology described elsewhere herein to measure various film properties, such as thickness, roughness, composition, and may further be capable of characterizing grating parameters such as critical dimensions (CD), sidewall angle (SWA), feature height (HT) under vacuum in an automated manner. Examples include, but are not limited to, optical techniques like reflectometry and scatterometry. In particularly advantageous embodiments, in-vacuo optical CD (OCD) techniques are employed where the attributes of a grating formed in a starting material are monitored as the epitaxial growth proceeds.

The epitaxy chambers 405 and 415 perform particular growth operations on a substrate, as described elsewhere herein. In the exemplary embodiment, the epitaxy chamber 405 provides in-situ growth of a silicon alloy-group III-nitride epitaxial film stack. As further depicted in FIG. 4, the multi-chambered processing platform 400 further includes load lock chambers 430 and holding cassettes 435 and 445 coupled to the transfer chamber 401 including a robotic handler 450.

In one embodiment of the present invention, adaptive control of the multi-chambered processing platform 400 is provided by a controller 470. The controller 470 may be one of any form of general-purpose data processing system that can be used in an industrial setting for controlling the various subprocessors and subcontrollers. Generally, the controller 470 includes a central processing unit (CPU) 472 in communication with a memory 473 and an input/output (I/O) circuitry 474, among other common components. Software commands executed by the CPU 472, cause the multi-chambered processing platform 400 to, for example, load a substrate into the first epitaxy chamber 405, execute a first group IV semiconductor and/or group IV compound growth process and execute a group III-nitride growth process without interruption. The substrate may then be further transfer to a second epitaxy chamber 415 and execute a further growth process (e.g., active device layers of LED stack).

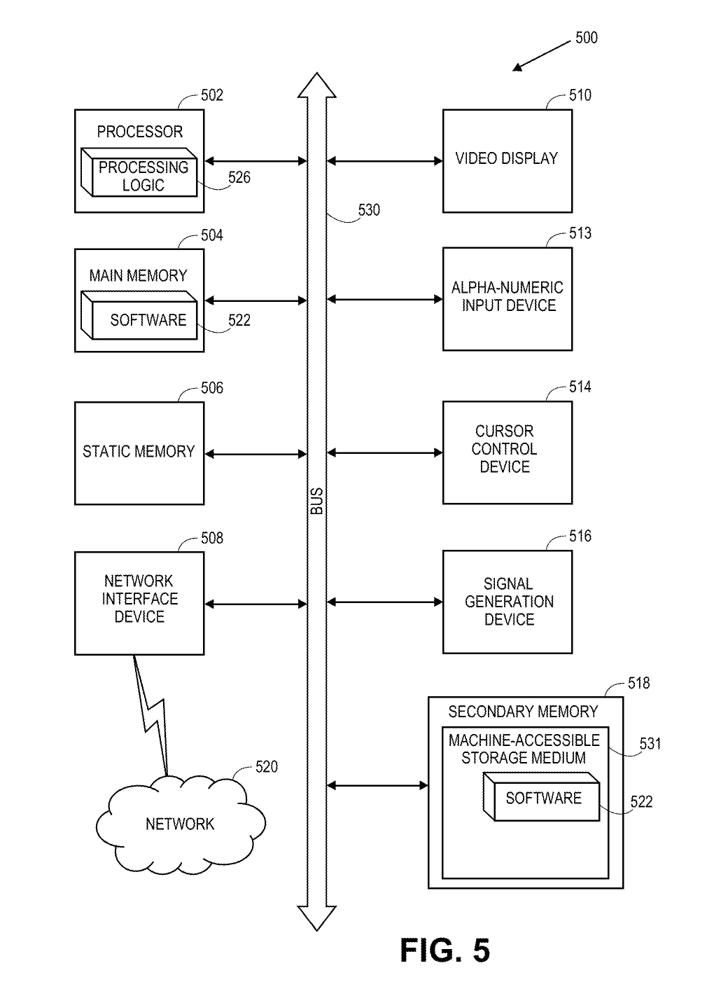

FIG. 5 illustrates a diagrammatic representation of a machine in the exemplary form of a computer system 500 which may be utilized to control one or more of the operations, process chambers or multi-chambered processing platforms described herein. In alternative embodiments, the machine may be connected (e.g., networked) to other machines in a Local Area Network (LAN), an intranet, an extranet, or the Internet. The machine may operate in the capacity of a server or a client machine in a client-server network environment, or as a peer machine in a peer-to-peer (or distributed) network environment. The machine may be a personal computer (PC) capable of executing a set of instructions (sequential or otherwise) that specify actions to be taken by that machine. Further, while only a single machine is illustrated, the term “machine” shall also be taken to include any collection of machines (e.g., computers) that individually or jointly execute a set (or multiple sets) of instructions to perform any one or more of the methodologies discussed herein.

The exemplary computer system 500 includes a processor 502, a main memory 504 (e.g., read-only memory (ROM), flash memory, dynamic random access memory (DRAM) such as synchronous DRAM (SDRAM) or Rambus DRAM (RDRAM), etc.), a static memory 506 (e.g., flash memory, static random access memory (SRAM), etc.), and a secondary memory 518 (e.g., a data storage device), which communicate with each other via a bus 530.

The processor 502 represents one or more general-purpose processing devices such as a microprocessor, central processing unit, or the like. More particularly, the processor 502 may be a complex instruction set computing (CISC) microprocessor, reduced instruction set computing (RISC) microprocessor, very long instruction word (VLIW) microprocessor, processor implementing other instruction sets, or processors implementing a combination of instruction sets. The processor 502 may also be one or more special-purpose processing devices such as an application specific integrated circuit (ASIC), a field programmable gate array (FPGA), a digital signal processor (DSP), network processor, or the like. The processor 502 is configured to execute the processing logic 526 for performing the process operations discussed elsewhere herein.

The computer system 500 may further include a network interface device 508. The computer system 500 also may include a video display unit 510 (e.g., a liquid crystal display (LCD) or a cathode ray tube (CRT)), an alphanumeric input device 513 (e.g., a keyboard), a cursor control device 514 (e.g., a mouse), and a signal generation device 516 (e.g., a speaker).

The secondary memory 518 may include a machine-accessible storage medium (or more specifically a computer-readable storage medium) 531 on which is stored one or more sets of instructions (e.g., software 522) embodying any one or more of the methods or functions described herein. The software 522 may also reside, completely or at least partially, within the main memory 504 and/or within the processor 502 during execution thereof by the computer system 500, the main memory 504 and the processor 502 also constituting machine-readable storage media. The software 522 may further be transmitted or received over a network 520 via the network interface device 508.

The machine-accessible storage medium 531 may further be used to store a set of instructions for execution by a processing system and that cause the system to perform any one or more of the embodiments of the present invention. Embodiments of the present invention may further be provided as a computer program product, or software, that may include a machine-readable medium having stored thereon instructions, which may be used to program a computer system (or other electronic devices) to perform a process according to the present invention. A machine-readable medium includes any mechanism for storing or transmitting information in a form readable by a machine (e.g., a computer). For example, a machine-readable (e.g., computer-readable) medium includes a machine (e.g., a computer) readable storage medium (e.g., read only memory (“ROM”), random access memory (“RAM”), magnetic disk storage media, optical storage media, and flash memory devices, etc.).

It is to be understood that the above description is intended to be illustrative, and not restrictive. Many other embodiments will be apparent to those of skill in the art upon reading and understanding the above description. Although the present invention has been described with reference to specific exemplary embodiments, it will be recognized that the invention is not limited to the embodiments described, but can be practiced with modification and alteration. Accordingly, the specification and drawings are to be regarded in an illustrative sense rather than a restrictive sense.

What is claimed is:

1. A method for growing a group III-nitride epitaxially on a substrate, the method comprising:
loading the substrate into an epitaxy chamber;
depositing a layer comprising a silicon semiconductor over the substrate;
depositing a group III-nitride epitaxial film over the substrate; and
unloading the substrate from the epitaxy chamber.

2. The method as in claim 1, wherein the substrate is silicon, wherein the silicon semiconductor is a silicon alloy epitaxial layer grown directly on the silicon substrate and wherein the group III-nitride epitaxial film is grown directly on the silicon alloy epitaxial layer.

3. The method as in claim 2, wherein depositing the silicon alloy epitaxial layer further comprises epitaxially growing a silicon alloy including at least one of germanium (Ge), carbon (C), and tin (Sn), on a silicon substrate.

4. The method as in claim 2, wherein depositing the silicon alloy epitaxial layer further comprises epitaxially growing a silicon germanium (SiGe) film on the silicon substrate, and wherein depositing the group III-nitride film further comprises epitaxially growing a film comprising gallium and nitride over the silicon germanium film.

5. The method as in claim 4, wherein the silicon alloy epitaxial layer comprises a SiGe superlattice or a compositionally graded SiGe film.

6. The method as in claim 4, wherein depositing the SiGe film comprises:
introducing at least 10 liters/min of germanium precursor and at least 10 liters/min of a silicon precursor into the chamber while the silicon substrate is heated to a temperature between 600° C. and 900° C.

7. The method as in claim 6, wherein depositing the GaN film further comprises:
heating the silicon substrate to at least 1000° C.;
discontinuing the introduction of the germanium and the silicon precursors; and
introducing a metalorganic precursor into the chamber.

8. The method as in claim 7, wherein, subsequent to the silicon alloy epitaxial layer deposition the silicon substrate is heated from the 600-900° C. temperature to the at least 1000° C. prior to introducing the metalorganic precursor.

9. The method as in claim 6, wherein the silicon precursor is selected from the group consisting of: silicon tetrachloride, silane, dichlorosilane, trichlorosilane and wherein the germanium precursor is selected from the group consisting of: germane, di-germane, and germanium tetrachloride.

10. The method as in claim 1, wherein the silicon semiconductor is Si, wherein the group III-nitride epitaxial film is a nucleation layer, and where the method further comprises growing a GaN film over the nucleation layer in a second deposition chamber.

11. A system for processing a substrate, the system comprising:
a first precursor delivery system configured to be coupled to both a silicon precursor and a second group IV precursor;
a second precursor delivery system configured to be coupled to a metalorganic precursor; and
a hybrid deposition chamber coupled to each of the first and second precursor delivery systems to grow both a transition film comprising either group IV semiconductor or group IV compound and a film comprising a group III-nitride on the transition film.

12. The system as in claim 11, wherein the hybrid deposition chamber comprises a metalorganic chemical vapor deposition (MOCVD) chamber configured to perform SiGe CVD or SiC CVD.

13. The system as in claim 11, wherein the first precursor delivery system is configured to provide the silicon precursor to the hybrid deposition chamber at a flow rate of least 10 liters/min.

14. The system as in claim 13, wherein the first precursor delivery system is configured to provide a germanium precursor to the hybrid deposition chamber at a flow rate of least 10 liters/min.

15. The system as in claim 14, wherein the first precursor delivery system is configured to provide each of the silicon and germanium precursors at rate of at least 20 liters/min.

16. The system as in claim 11, wherein the second group IV precursor comprises carbon (C) or tin (Sn).

17. The system as in claim 11, further comprising:
a transfer module coupled to the hybrid deposition chamber;
a robotic handler within the transfer module to transfer a substrate to and from the hybrid deposition chamber; and
a second epitaxy chamber to execute a further growth process on substrate after growth of the group III-nitride grown on the transition film.

18. The system as in claim 17, wherein the transition film comprises SiC and wherein the second epitaxy is dedicated on only group III-nitride film growth to remain carbon-free.

19. A computer-readable medium having stored thereon a set of instructions which when executed cause a system to perform a method comprising of:
loading a substrate into an epitaxy chamber;
depositing a film comprising either group IV semiconductor or group IV compound on the substrate;
depositing a group III-nitride film on the film comprising either group IV semiconductor or group IV compound; and
unloading the substrate from the epitaxy chamber.

20. The computer-readable medium of claim 18, further comprising instructions for:
epitaxially growing a silicon germanium (SiGe) film on a silicon substrate, and wherein depositing the group III-nitride film further comprises epitaxially growing a gallium nitride (GaN) film over the silicon germanium film.
